(19) United States
(12) Patent Application Publication
(10) Pub. No.: US 2007/0094571 A1
(43) Pub. Date: Apr. 26, 2007

(54) ECC circuit of semiconductor memory circuit

(75) Inventor: Jeong-Woo Lee, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/545,867

(22) Filed: Oct. 11, 2006

(30) Foreign Application Priority Data
Oct. 11, 2005 (KR) 2005-95551

(51) Int. Cl. G11C 29/00

(52) U.S. Cl. 714/763

(57) ABSTRACT

An error detection and correction (EEC) circuit of a semiconductor memory device includes first through m'th ECC engines (m is a natural number) connected in series, and a flipflop that receives output data from the m'th ECC engine, outputs an error detection/correction signal in response to a clock signal, and provides the error detection/correction signal to the first ECC engine. Each ECC engine receives output data from the former ECC engine and n-bit data (n is a natural number) from an ECC data input circuit. The ECC circuit is able to process m*n-bit data by means of the serially connected n-bit ECC engines arranged in number of m.

### CROSS-REFERENCE TO RELATED APPLICATIONS

This U.S. non-provisional patent application claims priority under 35 U.S.C. § 119 to Korean Patent Application 2005-95551 filed on Oct. 11, 2005, the entire contents of which are herein incorporated by reference.

### BACKGROUND

1. Technical Field

The present invention relates to semiconductor memory devices, and more particularly to an error detection and correction circuit (hereinafter, referred to as an ECC circuit) of a semiconductor memory device.

2. Description of Related Art

Semiconductor memory devices store data for later retrieval. Semiconductor memory devices may be classified into random access memories (RAMs) and read-only memories (ROMs). RAMs are nonvolatile memories that lose stored data when a power supply is turned off. ROMs are nonvolatile memories that retain stored data even without a power supply. The ROMs include programmable ROMs (PROMs), erasable PROMs (EPROMs), electrically EPROMs, and flash memories. The flash memories may be differentiated into NAND and NOR types.

A semiconductor memory may include functionality to detect and correct bit errors. An error correction code (ECC) circuit is used to detect and correct the bit errors. The ECC circuit generates first parity bits for detecting and correcting bit errors during a write operation. The first parity bits generated by the ECC circuit are written into memory cells along with program data. The ECC circuit generates second parity bits from the read data while reading the programmed data from the memory cells. The semiconductor memory device detects and corrects errors according to a comparison of the first parity bits of the write operation and the second parity bits of the read operation.

FIG. 1 is a block diagram showing an ECC circuit 100. Referring to FIG. 1, the ECC circuit 100 includes an n-bit ECC engine 101 (n is a positive integer), and a flip-flip (F/F) 110. The n-bit ECC engine 101 receives n-bit data from an ECC data input circuit 120.

The ECC circuit 100 is designed for a predetermined number of data bits provided from the ECC data input circuit 120. For example, the ECC circuit 100 is designed to receive 8-bit data from ECC data input circuit 120. Therefore, when the number of data bits from the ECC data input circuit 120 increases, the ECC circuit 100 may not function. Accordingly, a newly designed ECC engine is needed whenever the data bit number increases.

### SUMMARY OF THE INVENTION

According to an embodiment of the present invention, an ECC circuit of a semiconductor memory device comprises first through m'th ECC engines (m is a natural number) connected in series, and a flipflop receiving output data from the m'th ECC engine, outputting an error detection/correction signal in response to a clock signal, and providing the error detection/correction signal to the first ECC engine. Each ECC engine receives output data from a prior ECC engine in the series and n-bit data (n is a natural number) from an ECC data input circuit.

In an embodiment, the ECC circuit is connected with the ECC data input circuit through an m*n-bit bus. Each ECC engine receives the n-bit data from the ECC data input circuit in response to the clock signal.

According to an embodiment of the present invention an ECC circuit comprises a first ECC engine receiving first n-bit data (n is a natural number) from an ECC data input circuit and generating a first error detection/correction signal, a second ECC engine receiving the first error detection/correction signal and second n-bit data from the ECC data input circuit and generating a second error detection/correction signal, and a flipflop outputting the second error detection/correction signal in response to a clock signal. The flipflop provides the second error detection/correction signal to the first ECC engine in response to the clock signal.

In an embodiment, the first ECC engine further receives the second error detection/correction signal. The ECC circuit is connected with the ECC data input circuit through a 2n-bit bus. The first and second ECC engines receive the first and second n-bit data, respectively, from the ECC data input circuit in response to the same clock signal.

According to an embodiment of the present invention, an ECC circuit of a semiconductor memory device comprises first through m'th ECC engines (m is a natural number) connected in series, each ECC engine receiving n-bit data (n is a natural number) from an ECC data input circuit, and a selection circuit enabling i*n-bit data (i is a natural number between 1 and m) to be processed in response to a selection signal.

In an embodiment, the selection circuit enables n-bit data or m*n-bit data to be processed in response to the selection signal. The selection circuit comprises: a first flipflop receiving output data of the first ECC engine and a first error detecting/correction signal in response to a clock signal; an m'th flipflop receiving output data of the m'th ECC engine and an m'th error detecting/correction signal in response to the clock signal; a first selection circuit providing one of the first and m'th error detecting/correction signals to the first ECC engine in response to the selection signal; and a second selection circuit providing one of the first and m'th error detecting/correction signals to the first ECC engine in response to the selection signal.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified. In the figures:

FIG. 1 is a block diagram showing an ECC circuit;

FIG. 2 is a block diagram illustrating an ECC circuit in accordance with an embodiment of the present invention;

FIG. 3 is a block diagram exemplarily illustrating the ECC circuit shown in FIG. 2;

FIG. 4 is a block diagram illustrating an ECC circuit in accordance with another embodiment of the present invention; and

FIG. 5 is a block diagram illustrating an ECC circuit in accordance with still another embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to embodiments set forth herein. Rather, embodiments are provided so that this disclosure will be thorough and complete.

According to an embodiment of the present invention, an ECC circuit processes m*n-bit data by means of m serially connected ECC engines, each of which receives n-bit data.

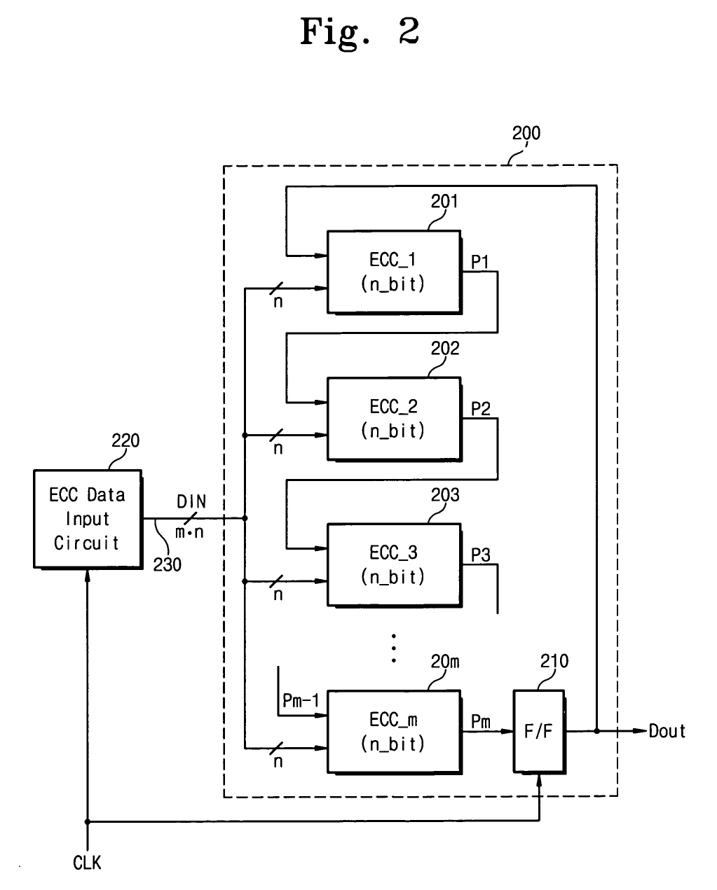

FIG. 2 is a block diagram illustrating an ECC circuit in accordance with an embodiment of the present invention. Referring to FIG. 2, the ECC circuit 200 is coupled with an ECC data input circuit 220 by way of a bus 230. The ECC data input circuit 220 provides m*n-bit data to the ECC circuit 200 through the bus 230 in response to a clock signal. CLK.

As shown in FIG. 2, the ECC circuit 200 is comprised of a plurality of ECC engines 201˜20m, and a flipflop (F/F) 210. The plurality of ECC engines 201˜20m are connected in series, each of which receives n-bit data from the ECC data input circuit 220.

A first ECC engine 201 receives n-bit data from the ECC data input circuit 220 and generates a first error detection/correction signal P1. A second ECC engine 202 receives n-bit data from the ECC data input circuit 220 and the first error detection/correction signal P1 from the first ECC engine 201, and generates a second error detection/correction signal P2. A third ECC engine 203 receives n-bit data from the ECC data input circuit 220 and the second error detection/correction signal P2 from the second ECC engine 201, and generates a third error detection/correction signal P3. Such input/output operations are repeated along the serial interconnections of the m-ECC engines. Thus, an m'th ECC engine 20m receives n-bit data from the ECC data input circuit 220 and the (m−1)'th error detection/correction signal Pm−1 from the (m−1)'th ECC engine, and generates an m'th error detection/correction signal Pm. Each of the plurality of ECC engines 201˜20m receives the n-bit data from the ECC data input circuit 220 in response to the same clock signal CLK.

The flipflop 210 receives and outputs (Dout) the m'th error detection/correction signal Pm in response to the clock signal CLK. The flipflop 210 provides the m'th error detection/correction signal Pm to the first ECC engine 201.

The ECC circuit 200 according to an embodiment of the present invention scales to process different numbers of data bits by means of an n-bit ECC engine even when the number of data bits from the ECC data input circuit 220 increases. According to an embodiment of the present invention, the ECC engine need not be redesigned to process increasing numbers of data bits from the ECC data input circuit 220.

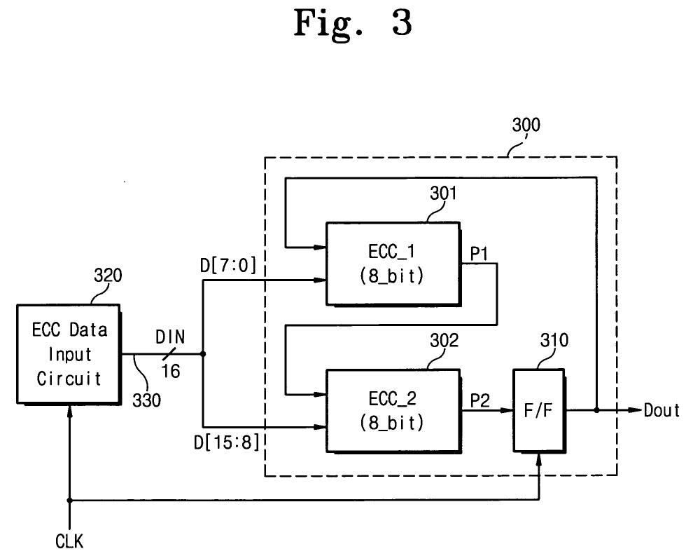

FIG. 3 is a block diagram illustrating an exemplary embodiment of the ECC circuit shown in FIG. 2. Referring to FIG. 3, the ECC circuit 300 is comprised of two ECC engines each receiving 8-bit data. Thus, the ECC circuit 300 is able to process up to 16-bit data supplied from the ECC data input circuit 320.

As illustrated in FIG. 3, the ECC circuit 300 includes first and second ECC engines 301 and 302 serially connected to each other, and a flipflop 310. The first and second ECC engines 301 and 302 each receive 8-bit data. The first ECC engine 301 receives lower 8-bit data D[7:0] from the ECC data input circuit 320 and generates the first error detection/correction signal P1. The second ECC engine 302 receives higher 8-bit data D[15:8] from the ECC data input circuit 320 and the first error detection/correction signal P1 from the first ECC engine 301, and generates the second error detection/correction signal P2. The flipflop 310 provides the second detection/correction signal P2 to the first ECC engine 301.

In the ECC circuit 300 shown in FIG. 3, 16-bit data is processed through the two 8-bit ECC engines. The ECC circuit processes m*n-bit data by means of the m serially connected n-bit ECC engines, with no need for redesigning the ECC engine to handle a different number of data bits.

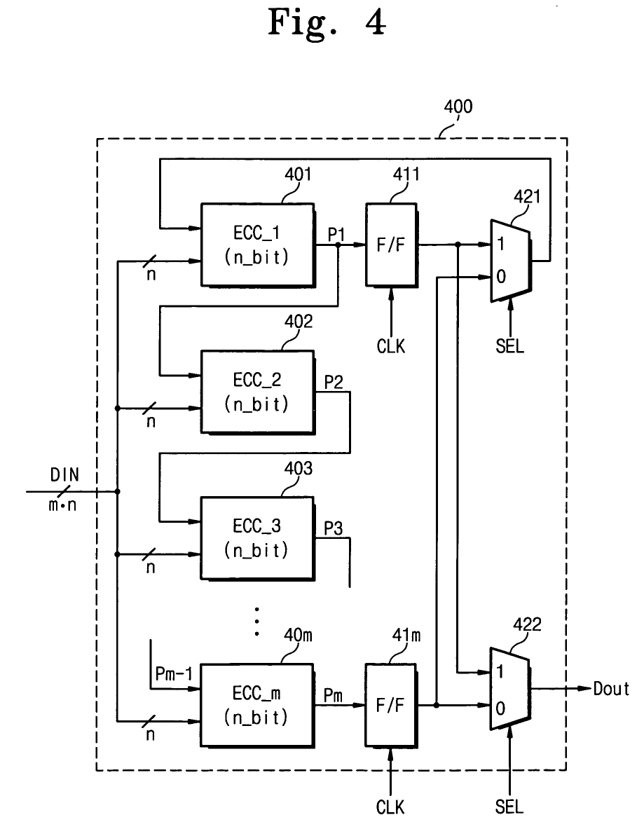

FIG. 4 is a block diagram illustrating an ECC circuit 400 in accordance with another embodiment of the present invention. The ECC circuit 400 shown in FIG. 4 is comprised of a plurality of ECC engines 401˜40m, a plurality of flipflops 411˜41m, and first and second selection circuits 421 and 422. The plurality of flipflops 411˜41m are substantially the same as the flipflop 210 shown in FIG. 2.

A first flipflop 411 receives the first error detection/correction signal P1 from the first ECC engine 401 and provides the first error detection/correction signal P1 to the first and second selection circuits 421 and 422 in response to the clock signal CLK. The m'th flipflop 41m receives the m'th error detection/correction signal Pm from the m'th ECC engine 40m and provides the m'th error detection/correction signal Pm to the first and second selection circuits 421 and 422 in response to the clock signal CLK.

The first selection circuit 421 provides one of the first and m'th error detection/correction signals P1 and Pm to the first ECC engine 401 in response to a selection signal SEL. The second selection circuit 422 outputs (Dout) one of the first and m'th error detection/correction signals P1 and Pm in response to the selection signal SEL.

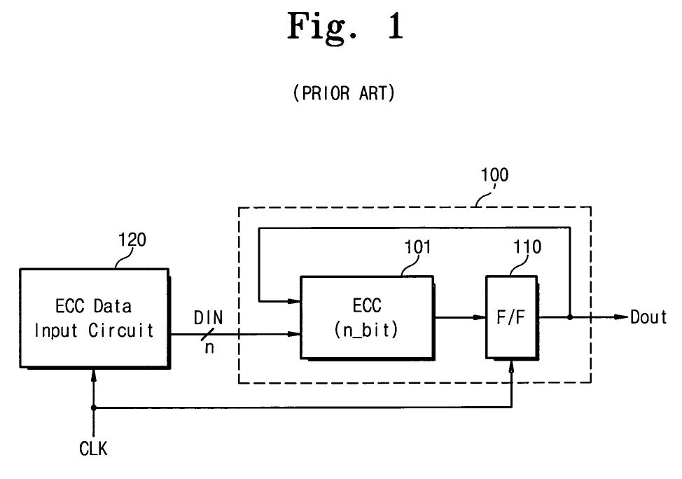

The ECC circuit 400 shown in FIG. 4 processes n-bit data or m*n-bit data in compliance with the selection signal SEL. The ECC circuit 400 shown in FIG. 4 may be used as an n-bit ECC engine (refer to FIG. 1), or an m*n-bit ECC Engine (refer to FIG. 2). For example, the ECC circuit 400 shown in FIG. 4 operates substantially similar to the ECC circuit 100 shown in FIG. 1 when the selection signal is set on ‘1’, or operates substantially similar to the ECC circuit 200 shown in FIG. 2 when the selection signal is set on, ‘0’.

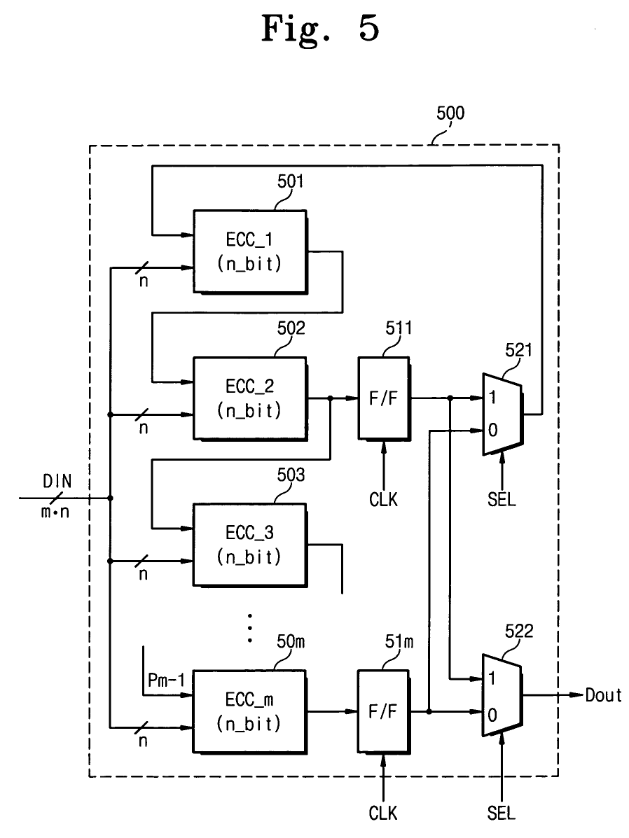

The ECC circuit 500 shown in FIG. 5 processes 2n-bit data substantially similar to the ECC circuit 300 shown in FIG. 3, when the selection signal is set on ‘1’, while processing m*n-bit data, and processes 2n-bit data substantially similar to the ECC circuit 200 shown in FIG. 2, when the selection signal is set on ‘0’.

Referring to FIGS. 4 and 5, the ECC circuit according to an embodiment of the present invention may be implemented as an n-bit ECC engine, an 2n-bit ECC engine, 3n-bit ECC engine, . . . , or m*n-bit ECC engine, according to operational needs.

The ECC circuit according to an embodiment of the present invention handles increasing data widths by means of a n-bit ECC engine. According to an embodiment of the present invention, the ECC engine need not be redesigned to handle increasing numbers of data bits from the ECC data input circuit.

Further, when the n-bit ECC engine uses the Reed-Solomon algorithm, the ECC circuit reduces the number of parity bits. For example, assuming a a 64-bit ECC circuit with a 8-bit ECC engine detects and stores a 2-bit error, the number of parity bits in the ECC engine with the Reed-Solomon algorithm is obtained by
P=2×T×S [Equation 1]

In Equation 1, T is the number of correcting errors and S is the number of input data bits.

With eight 8-bit ECC engines, the number of parity bits, P1, is 32 bits, wherein P1=2*2*8=32. Otherwise, with a single 64-bit ECC engine, the number of parity bits, P2, is 256 bits, wherein P2=2*2*64=256. As such, the ECC circuit uses a reduced number of parity bits.

The ECC circuit according to an embodiment of the present invention processes m*n-bit data by means of m serially connected n-bit ECC engines. Thus, there is no need for updating the ECC engine to handle an increasing number of input data bits.

Exemplary embodiments described herein are to be considered illustrative, and not restrictive, and the appended claims are intended to cover all modifications, enhancements, and other embodiments, which fall within the spirit and scope of the disclosure.

What is claimed is:

1. An error detection and correction (ECC) circuit of a semiconductor memory device, comprising:
first through m'th ECC engines connected in series, wherein m is a natural number; and
a flipflop receiving output data from the m'th ECC engine, outputting an error detection/correction signal in response to a clock signal, and providing the error detection/correction signal to the first ECC engine, wherein each ECC engine receives output data from a prior ECC engine in the series and n-bit data from an ECC data input circuit, wherein n is a natural number.

2. The ECC circuit as set forth in claim 1, which is connected with the ECC data input circuit through an m*n-bit bus.

3. The ECC circuit as set forth in claim 1, wherein each ECC engine receives the n-bit data from the ECC data input circuit in response to the clock signal.

4. An error detection and correction (ECC) circuit comprising:
a first ECC engine receiving first n-bit data from an ECC data input circuit and generating a first error detection/correction signal, wherein n is a natural number;
a second ECC engine receiving the first error detection/correction signal and second n-bit data from the ECC data input circuit and generating a second error detection/correction signal; and
a flipflop outputting the second error detection/correction signal in response to a clock signal,
wherein the flipflop provides the second error detection/correction signal to the first ECC engine in response to the clock signal.

5. The ECC circuit as set forth in claim 4, wherein the first ECC engine further receives the second error detection/correction signal.

6. The ECC circuit as set forth in claim 4, which is connected with the ECC data-input circuit through a 2n-bit bus.

7. The ECC circuit as set forth in claim 4, wherein the first and second ECC engines receive the first and second n-bit data, respectively, from the ECC data input circuit in response to the clock signal.

8. An error detection and correction (ECC) circuit of a semiconductor memory device, comprising:
first through m'th ECC engines connected in series, each ECC engine receiving n-bit data from an ECC data input circuit, wherein m and n are the same or different natural numbers; and
a selection circuit enabling i*n-bit data to be processed in response to a selection signal, wherein i is a natural number between 1 and m.

9. The ECC circuit as set forth in claim 9, wherein the selection circuit comprises:
a first flipflop receiving output data of the first ECC engine and a first error detecting/correction signal in response to a clock signal;
an m'th flipflop receiving output data of the m'th ECC engine and an m'th error detecting/correction signal in response to the clock signal;
a first selection circuit providing one of the first and m'th error detecting/correction signals to the first ECC engine in response to the selection signal; and
a second selection circuit providing one of the first and m'th error detecting/correction signals to the first ECC engine in response to the selection signal.

10. The ECC circuit as set forth in claim 9, wherein the first selection circuit provides the first error detecting/correction signals to the first ECC engine in response to the selection signal,
wherein the second selection circuit provides the first error detecting/correction signals to the first ECC engine in response to the selection signal.

11. The ECC circuit as set forth in claim 9, wherein the first selection circuit provides the m'th error detecting/correction signals to the first ECC engine in response to the selection signal,
wherein the second selection circuit provides the m'th error detecting/correction signals to the first ECC engine in response to the selection signal.

12. The ECC circuit as set forth in claim 8, wherein each ECC engine receives the n-bit data from the ECC data input circuit in response to the clock signal.
